(19) United States
(12) Patent Application Publication
(10) Pub. No.: US 2013/0119427 A1
(43) Pub. Date: May 16, 2013

(54) LED SUBSTRATE, LED CHIP AND METHOD FOR MANUFACTURING THE SAME

(71) Applicant: Ge Zhang, Shenzhen (CN)

(72) Inventor: Ge Zhang, Shenzhen (CN)

(73) Assignees: BYD Company Limited, Pingshan, Guangdong (CN); SHENZHEN BYD AUTO R&D COMPANY LIMITED, Guangdong (CN)

(21) Appl. No.: 13/700,876

(22) PCT Filed: May 17, 2011
(86) PCT No.: PCT/CN11/74205

§ 371 Date: Nov. 29, 2012

(30) Foreign Application Priority Data
May 29, 2010 (CN) 201010190330.3

(51) Int. Cl. H01L 33/62

(52) U.S. Cl. CPC H01L 33/62
USPC 257/99; 438/22

(57) ABSTRACT

An LED substrate may comprise a base including a first surface and a second surface; and a conductive structure formed on at least a part of the first surface and at least a part of the second surface, the part of the conductive structure formed on the first surface electrically connected to the part of the conductive structure formed on the second surface. A method for forming an LED substrate, a method for forming an LED chip, and an LED chip manufactured therefrom may be provided as well.

### CROSS-REFERENCE OF RELATED APPLICATIONS

The present application is a national phase entry under 35 U.S.C. §371 of International Application No. PCT/CN2011/074205 filed May 17, 2011, which claims priority from Chinese Patent Application No. 201010190330.3, filed May 29, 2010, all of which are incorporated herein by reference.

### FIELD

The present disclosure generally relates to a semiconductor device, more particularly, to an LED substrate, a light emitting diode (LED) chip and manufacturing method thereof.

### BACKGROUND

Most epitaxial layers of the light emitting diode (LED) are manufactured on the sapphire substrate. Because the sapphire substrate is an insulator, when the common light emitting diode chip is manufactured, a part of the epitaxial layer needs to be etched to form an electrode, which is complex with high cost in addition to wasted materials. And when a vertical structure light emitting diode chip is manufactured, the sapphire substrate needs to be stripped by a laser lift-off process, which is also complicated and high in cost.

FIGS. 1A to 1D show a manufacturing procedure of a conventional light emitting diode. First, a sapphire base 100 is provided. Then, a light emitting epitaxial structure 102 is formed on the sapphire base 100 as shown in FIG. 1A. The light emitting epitaxial structure 102 includes a first type semiconductor layer, an active layer and a second type semiconductor layer sequentially formed on the sapphire base 100. Then, the light emitting epitaxial structure 102 is bonded to a conductive base 104, as shown in FIG. 1B. Because the sapphire base 100 is an insulator, when the vertical conductive electrode structure is manufactured, the conductive base 104 needs to be provided, and the sapphire base 100 needs to be stripped. The sapphire base 100 is stripped by the laser lift-off process to expose the light emitting epitaxial structure 102, as shown in FIG. 1C. Then, a first electrode 106 and a second electrode 108 are formed on an upper surface of the light emitting epitaxial structure 102 and a lower surface of the conductive base 104 respectively. Finally, a plurality of LED chips may be formed by cutting, as shown in FIG. 1D.

During the manufacturing procedure, when the sapphire base 100 is removed by the laser lift-off process, the LED structure will be damaged because of the stress caused by the high temperature or the temperature difference during laser processing. Furthermore, during stripping, the characteristics of the LED chip may become poor due to high energy transfer, so that the yield rate of the LED may be decreased. Moreover, the light emitting epitaxial structure 102 needs to be stuck to the conductive base 104, which will increase the cost and decrease the pass rate.

### SUMMARY

The present disclosure is directed to solve at least one of the problems existing in the prior art. Accordingly, an LED substrate may need to be provided, which may reduce process complexity as well as high cost. Further, a method for forming an LED substrate, a method for forming an LED chip and an LED chip may need to be provided as well.

According to an aspect of the present disclosure, an LED substrate may be provided. The LED substrate may comprise a base including a first surface and a second surface; and a conductive structure formed on at least a part of the first surface and at least a part of the second surface, the part of the conductive structure formed on the first surface electrically connected to the part of the conductive structure formed on the second surface.

According to another aspect of the present disclosure, a method for forming an LED substrate may be provided. The method may comprise A) providing a base including a first surface and a second surface; B) coating a photoresist on the first surface of the base to form a photoresist layer, and a part of the photoresist layer coated on the first surface comprising a photoresist pattern; C) forming an intermediate layer including a conductive material on the surfaces of the base uncovered by the photoresist layer; D) removing the photoresist layer; and E) performing a heat treatment to convert the intermediate layer into a conductive structure.

According to still another aspect of the present disclosure, a method for forming an LED chip may be provided. The method may comprise: providing an LED substrate as described hereinabove; forming an epitaxial layer above the conductive structure formed on the first surface, wherein the epitaxial layer includes a first type semiconductor layer, an active layer and a second type semiconductor layer, which are formed on the pattern of the conductive layer successively; forming a first electrode on a part of the conductive structure disposed on the second surface or of the base; and forming a second electrode on the second type semiconductor layer.

According to still another aspect of the present disclosure, a method for forming an LED chip may be provided. The method may comprise: providing an LED substrate mentioned above; forming an epitaxial layer on the conductive structure formed on the first surface in which the epitaxial layer includes a first type semiconductor layer, an active layer and a second type semiconductor layer, which are formed on the pattern of the conductive structure successively; forming a first electrode on the second type semiconductor layer; dicing the substrate into a plurality of pieces; performing an extending treatment to form a separating space between the pieces; dropping a conductive resin in the separating space to form the conductive structure on a lateral side of the piece to electrically connect with the part of the conductive structure formed on the first surface of the base; and forming a second electrode on the lateral side of each of the pieces.

According to yet another aspect of the present disclosure, an LED chip may be provided. The LED chip may comprise: an LED substrate mentioned above; a first type semiconductor layer formed on the conductive structure formed on the first surface; an active layer formed on the first type semiconductor layer; a second type semiconductor layer formed on the active layer; a first electrode formed on conductive structure formed on the second surface; and a second electrode formed on the second type semiconductor layer.

According to the above embodiments of the present disclosure, a conductive structure may be formed on more than one surface of the base and the semiconductor structure may be formed on the conductive structure formed the second surface or the third surface, the laser lift-off process and the step of bonding an additional conductive layer may not be needed, which simplifies the manufacturing process and decreases the cost accordingly, especially during the process of forming a vertical structure LED chip on the substrate as disclosed herein.

### BRIEF DESCRIPTION OF THE DRAWINGS

These and other aspects and advantages of the disclosure will become apparent and more readily appreciated from the following descriptions taken in conjunction with the drawings, in which:

FIGS. 1A to 1D show sequential views of forming a conventional vertical light emitting diode;

FIG. 2A is a perspective view of an LED substrate according to a first embodiment of the present disclosure;

FIG. 2B is a top view of the LED substrate in FIG. 2A;

FIG. 3A is a perspective view of an LED substrate according to a second embodiment of the present disclosure;

FIG. 3B is a top view of the LED substrate in FIG. 3A;

FIG. 4A is a perspective view of the LED substrate according to a third embodiment of the present disclosure;

FIG. 4B is a top view of the LED substrate in FIG. 4A;

FIGS. 5A to 5E are sequential views of a method for forming an LED substrate according to an embodiment of the present disclosure;

FIG. 6A is a cross-sectional view of the base formed with a photoresist pattern according to an embodiment of the present disclosure;

FIG. 6B is a cross-sectional view of the base formed with a photoresist pattern according to another embodiment of the present disclosure;

FIG. 7A is a top view of the base formed with a photoresist pattern according to another embodiment of the present disclosure;

FIG. 7B is a top view of the base formed with a photoresist pattern according to an embodiment of the present disclosure; and

FIG. 8 is a cross-sectional view of the LED chip according to an embodiment of the present disclosure.

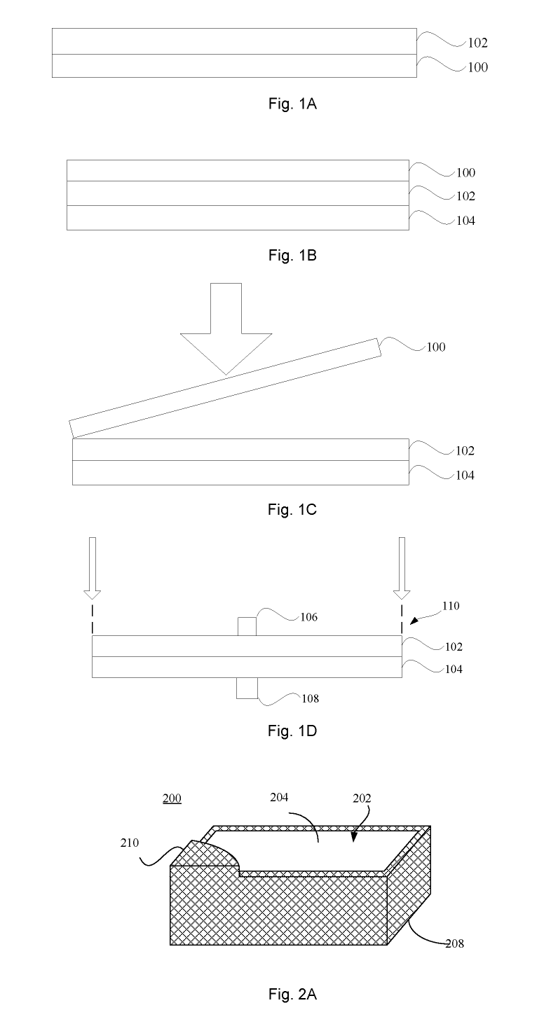

### DETAILED DESCRIPTION

Reference will be made in detail to embodiments of the present disclosure. The embodiments described herein with reference to the accompany drawings are explanatory and illustrative, which are used to generally understand the present disclosure. The embodiments shall not be construed to limit the present disclosure.

In one embodiment of the present disclosure, the LED substrate comprises: a base including a first surface and a second surface; and a conductive structure formed on at least a part of the first surface and at least a part of the second surface, the part of the conductive structure formed on the first surface electrically connected to the part of the conductive structure formed on the second surface. And semiconductor structures may be formed or grown on the conductive structure formed on the first surface accordingly. Due to the conductive structure formed on the base, the LED substrate may be conductive. In addition, when forming an LED chip, the base of the LED substrate may not need to be removed, thus reducing process complexity in addition to reduced cost. In some embodiment of the present disclosure, the part of the conductive structure formed on the first surface comprises a pattern exposing at least a part of the first surface. In some embodiment, the base may have a cubic or a parallelepiped shape. In some embodiment, the first surface is the upper surface of the base and the second surface is the bottom surface of the base. The part of the conductive structure formed on the first surface is electrically connected with the part of the conductive structure formed on the second surface through the part of the conductive structure formed on the third surface. In some embodiment, the first surface is the upper surface of the base and the second surface is the lateral side of the base. The part of the conductive structure formed on the first surface and the part of the conductive structure formed on the second surface may be integrally formed to electrically connect with each other.

In the following, embodiments of the LED substrate will be described in detail with reference to accompanying figures.

As shown in FIGS. 2A-2B, according to a first embodiment of the present disclosure, the LED substrate 200 comprises a base 202. In this embodiment of the present disclosure, the base 202 may be a cuboid including an upper surface 204, four lateral sides 206, and a bottom surface 208. As shown in FIGS. 2A-2B, a conductive structure 210 is formed on the base 202. In this embodiment of the present disclosure, the upper surface 204 is defined as the first surface, the bottom surface 208 is defined as the second surface, the lateral side 206 is defined as the third surface, and the conductive structure 210 is formed on the first surface, the second surface and the four third surfaces. The part of the conductive structure 210 formed on the first surface is electrically connected with the part of the conductive structure 210 formed on the second surface through the part of the conductive structure 210 formed on the third surface. The conductive structure 210 formed on the first surface comprises a pattern 212. The pattern 212 exposes a part of the base 202. In some embodiment, the conductive structure 210 is formed on the first surface, the second surface and at least one of the third surfaces.

In some embodiments, the base 202 may be formed from an insulating material such as sapphire, a weakly conductive material such as monocrystalline silicon or a conductive material such as silicon carbide. In one embodiment, the base 202 may be formed from sapphire. The shape of the base 202 may be a cube or a cylinder.

In this embodiment of the present disclosure, the base 202 is of a cubic shape. The pattern 212 in this embodiment is a quarter circle shape. In some embodiments, the pattern 212 may have a thickness of about 0.2-1.5 μm. In one embodiment, the pattern 212 may have a thickness of about 1 μm.

Alternatively, the material of the conductive structure 210 may be conductive ceramics or a metal. In this embodiment of the present disclosure, the conductive structure 210 is formed from metal. The metal may be aluminum, copper, gold, silver and so on. In one embodiment, the metal is aluminum or silver, which may form a reflecting barrier around the base 202, so when the substrate 200 is used as the substrate of an LED, the conductive structure 210 may reflect the light incident onto the base 202, which may increase the light efficiency of the LED. In some embodiments of the present disclosure, the thickness of the conductive structure 210 is substantially even.

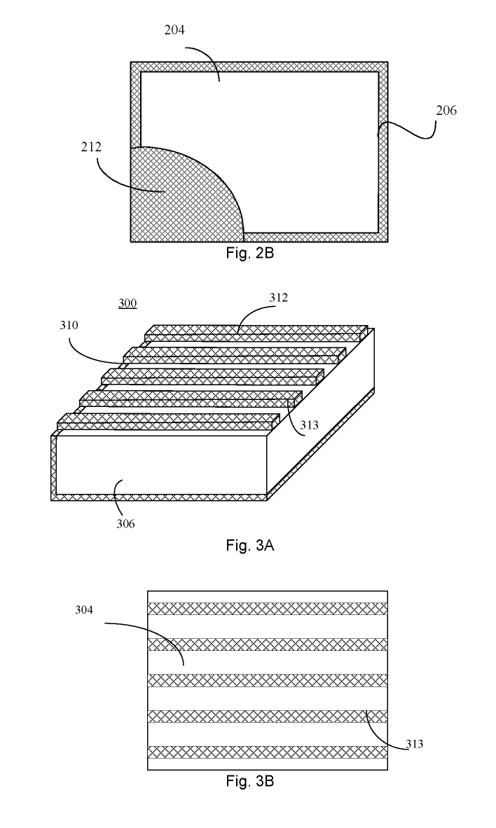

Referring to FIGS. 3A-3B, according to a second embodiment of the present disclosure, an LED substrate 300 is provided. It should be noted that different features or structures will be described in detail in the following, and the detailed description of the same or similar features as in the first embodiment will be described briefly. In some embodiment, the upper surface is defined as the first surface, the bottom surface is defined as the second surface, the lateral side is defined as the third surface. In this embodiment, the conductive structure 310 is formed on three surfaces of the base 302, i.e. the first surface 304, the second surface 308 and one third surface 306. The part of the conductive structure 310 formed on the first surface 304 is electrically connected with the part of the conductive structure 310 formed on the second surface 308 through the part of the conductive structure 310 formed on the third surface 306. The pattern 312 in this embodiment comprises a plurality of strips 313 spaced apart from each other. In one embodiment of the present disclosure, the strips 313 may not intersect. The strips 313 may be parallel or nonparallel to each other. In one embodiment of the present disclosure, at least two strips intersect. As shown in FIGS. 3A and 3B, the strips 313 are parallel. The distances between two neighboring strips 313 are equal. In some embodiments, the width of the strip 313 ranges from 5 to 15 μm. In some embodiment, the width of the strip is 10 μm and the distance between two neighboring strips is 10 μm.

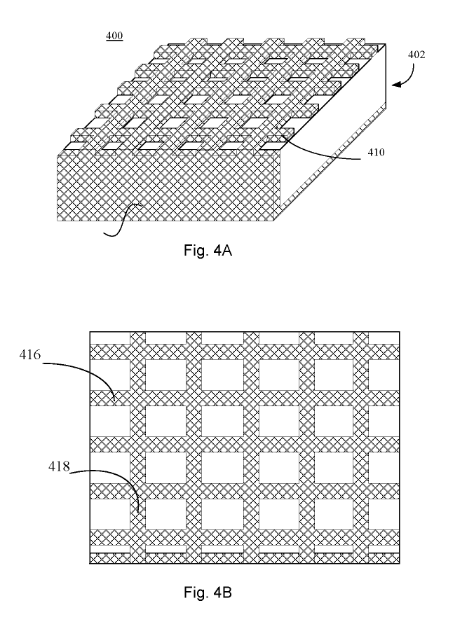

Referring to FIGS. 4A and 4B, another LED substrate 400 is provided. In this embodiment, the conductive structure 404 is formed on three surfaces of the base 402. The pattern 412 in this embodiment has a grid pattern, as shown in FIG. 4A. In some embodiment, the grid may have a circular, an elliptical or a polygonal shape. The polygon may be a triangle, a square, a pentagon, a hexagon and so on. As shown in FIGS. 4A and 4B, the grid pattern comprises a plurality of first strips 416 and a plurality of second strips 418 intersecting with the first strips 416, which form a plurality of rectangular grids. The distances between two neighboring first strips 416 or two neighboring second strips 418 are equal. The width of the strip is 10 μm and the distance between two neighboring strips is 10 μm.

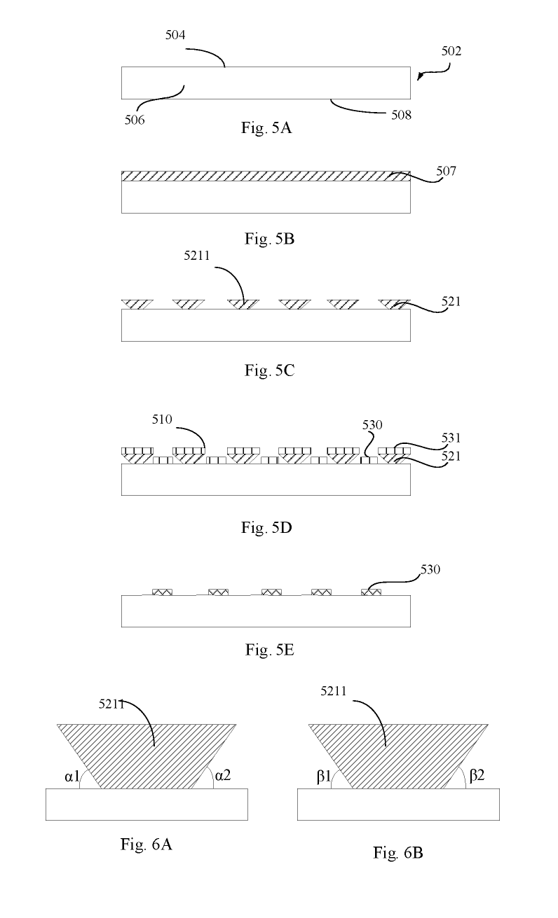

In the following, a method for forming an LED substrate according to an embodiment of the present disclosure will be described with reference to FIGS. 5A to 5E.

FIGS. 5A to 5E are sequential views of the method for forming an LED substrate according to an embodiment of the present disclosure. Referring to FIG. 5A, a base 502 is provided. The base 502 comprises a plurality of surfaces, including an upper surface (first surface) 504, four lateral sides (third surface) 506 and a bottom surface (second surface) 508. In some embodiment, the base 502 is formed from sapphire. As shown in FIG. 5B, a photoresist is coated on the first surface 504 of the base 502 to form a photoresist layer 507. In some embodiment, the photoresist is a negative photoresist. Referring to FIG. 5C, the photoresist layer 507 is exposed and developed to form a photoresist pattern 521 in the photoresist layer 507. At least a portion of the first surface 504 of the base 502 is uncovered by the photoresist pattern 521. In some embodiment, the photoresist pattern 521 is formed by a plurality of strips 5211 spaced apart from each other, with both lateral sides of the strips 5211 being slanted toward each other by acute angles respectively with respect to the first surface 504 of the base 502. The distances between two neighboring strips 5211 are equal. In some embodiment, the photoresist pattern 521 is formed by a plurality of projections spaced apart from each other with peripheral sides thereof being slanted toward each other by acute angles respectively with respect to the first surface 504 of the base 502, as shown in FIGS. 6A and/or 6B. In some embodiments, the shape of the projection may be a circle, an ellipse or a polygon. The polygon may be a triangle, a square, a pentagon, a hexagon and so on. In some embodiment, the acute angles range from 20° to 70° respectively.

Referring to FIGS. 6A and 6B, the projections or strips 5211 form angles with the first surface 504 of the base 502. As shown in FIG. 6A, a first lateral side of the projection or strip 5211 forms a first angle α1 with the first surface 504 of the base 502 and a second lateral side of the projection or strip 5211 forms a second angle α2 with the first surface 504 of the base 502. In some embodiment, the first angle α1 and the second angle α2 are no larger than 90 degrees. In one embodiment, the first angle α1 equals to the second angle α2. In another embodiment, the first angle α1 may not be equal to the second angle α2. As shown in FIG. 6B, when projections are formed on the first surface 504 of the base 502, a third lateral side of each projection forms a third angle β1 with the first surface 504 of the base 502 and a fourth lateral side of the projection forms a fourth angle β2 with the first surface 504 of the base 502. In some embodiment, the third angle β1 and the fourth angle β2 are no larger than 90 degrees. In some embodiment, the third angle β1 equals to the fourth angle β2. In some embodiment, the third angle β1 may not be equal to the fourth angle β2.

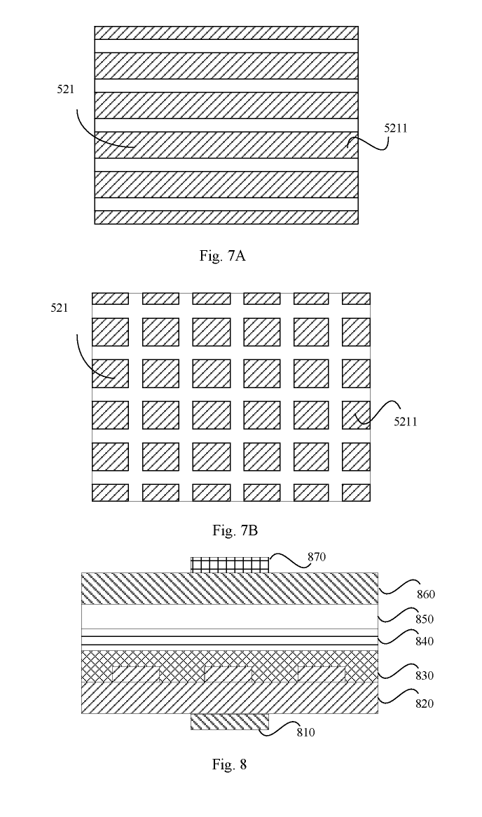

Referring to FIG. 7A, the photoresist pattern 521 comprises the plurality of strips 5211. The width of the strip 5211 equals to the interval of two neighboring strips of a pattern (not shown) to be formed. Referring to FIG. 7B, the photoresist pattern 521 comprises a plurality of projections 5211. The projections 5211 may be formed or disposed on the first surface 504 of the base 502 to form the pattern. And the pattern has a transferring relationship with the disposed projections 5211.

To form a photoresist pattern 521 by coating photoresist on the first surface 504 of the base 502, exposing and developing the photoresist layer 507 accordingly. To be specific, the base 502 may be processed as follows:

coating a negative photoresist on the first surface 504 of the base 502 by a coating machine (not shown) at a rotation speed of about 30 rps-45 rps for about 35 seconds or at a rotation speed of about 8 rps-11 rps for about 10 seconds to control a thickness of the photoresist pattern 521;

baking the base 502 with the first surface 504 being coated with the photoresist for about 12-16 minutes at a temperature of about 85-95° C.;

exposing the base 502 by using a light source with an energy of 20 J for about 6-12 seconds by a distance of about 60-250 μm;

developing the base 502 for about 50-70 seconds and washing the base 502 with water to remove the exposed photoresist to form a photoresist layer 507 with the photoresist pattern 521; and

baking the base 502 formed with the photoresist pattern 521 for about 20-30 minutes at a temperature of about 118-122° C.

In some embodiments, the photoresist pattern 521 has a thickness of about 1.8-3 μm. In this embodiment of the present disclosure, the base 502 is baked twice to determine the thickness and the pattern of the photoresist. And the lateral sides of projection or strip 5211 may form angles no larger than 90 degrees with the first surface 504 of the base 502. In some embodiment, the angles range from about 20 to about 70 degrees.

Referring to FIG. 5D and FIG. 5E, an intermediate layer 510 including a conductive material 531 is formed on the photoresist pattern 521 and a conductive material 530 is formed on the base 502. The intermediate layer 510 may be formed through a spraying method, a solvothermal method or a sol-gel method. In one embodiment, the intermediate layer 510 is formed on the first surface 504, at least a part of the second surface 508 and at least a part of the third surface 506 of the base 502.

In one embodiment of the present disclosure, the base is cuboid. The upper surface is defined as the first surface and the lateral side is defined as the second surface. In the method for forming an LED substrate, when the first surface of the base is coated with photoresist to form a photoresist layer, one or more than one second surfaces, but not all the second surfaces, is also coated with the photoresist, and the intermediate layer 510 is formed on the first surface and at least one of the second surfaces. And the part of the intermediate layer 510 formed on the first surface and the part of the intermediate layer 510 formed on the second surface are integrally formed to be electrically connected with each other. In some embodiment, when the first surface of the base is coated with photoresist to form a photoresist layer, at least one second surface, but not all the second surfaces are also coated with the photoresist.

In some embodiment of the present disclosure, the intermediate layer 510 is formed from a gelatinous precursor, the precursor may be an organic material complexed with metal ions or particles. Further, the molar ratio of alcohol to metal is about 5:1 and the concentration of aluminum isopropoxide or silver isopropoxide is about 0.5-1.4 mol/L.

In one embodiment, the intermediate layer 510 is formed from a gelatinous precursor by a sol-gel method comprising the steps of dissolving a metal alkoxide and a polymer in a organic solvent and stirring the organic solvent at a temperature of about 40-90° C. to form the gelatinous precursor. In some embodiments, the gelatinous precursor comprises easily thermal decomposed organic material and metal material. In one embodiment, the organic solvent is at least one solvent selected from ethanol, ethylene glycol, isopropanol and acetonitrile, and the polymer is polyvinyl alcohol, polyaniline or polypyrrole. In one embodiment, the metal alkoxide is aluminum isopropoxide or silver isopropoxide, and the polymer is polyvinyl alcohol. The aluminum isopropoxide or silver isopropoxide may form a reflective surface on the LED substrate to improve the light extracting rate of an LED chip.

Referring to FIG. 5D, the photoresist pattern 521 is removed to expose parts of the base 502 covered by the photoresist layer. To remove the photoresist layer, the base 502 is put into a stripper DTNS-4000 (not shown) commercially available from Shenzhen Detong Optoelectronic Material Co., Ltd. at a temperature of 70° C. for 15-30 minutes. Then the base 502 is put into acetone for 10-20 minutes; finally the base 502 is put into isopropyl ketone for 15-20 minutes. After that process, the photoresist is removed from the base 502. Later, the base 502 is subjected to a static electricity elimination treatment through a blue film and ion fan. First, the blue film is evenly pressed on the base, then the blue film is torn from the base, and the residual photoresist and metal are removed by adhering to the blue film. And the ion fan operates when the blue film is torn from the base.

In one embodiment of the present disclosure, the base 502 is subjected to a heat treatment to convert the intermediate layer 510 into a conductive structure. At least a portion of the first surface is uncovered by the conductive structure formed on the base 502. The heat treatment for the base 502 is performed in an annealing furnace filled with a protection gas such as an inert gas or nitrogen which will not react with the conductive material in the intermediate layer 510. The temperature of the annealing furnace is maintained in a range of about 200-400° C. for 1-2 hours. In order to avoid the oxidization of the metal, after the substrate in the furnace is cooled to the room temperature, the base 502 is taken out of the furnace to obtain the LED substrate.

In the following, a method of forming the LED chip will be described. The method may comprises: providing an LED substrate mentioned above; forming an epitaxial layer on the conductive structure formed on the first surface in which the epitaxial layer includes a first type semiconductor layer, an active layer and a second type semiconductor layer, which are formed on the pattern of the conductive structure successively; forming a first electrode on a part of the conductive structure disposed on the second surface or of the base; and forming a second electrode on the second type semiconductor layer.

In some embodiment of the present disclosure, the method of forming the LED chip further comprises the steps of: dicing the substrate into a plurality of pieces or dies; performing an extending treatment to form a separating space between the pieces; dropping a conductive resin in the separating space to form the conductive structure on a lateral side of the piece. In some embodiment, the separating space is about 500 μm.

In the following, a method of forming the LED chip will be described. The method may comprise: providing an LED substrate mentioned above; forming an epitaxial layer on the conductive structure formed on the first surface, in which the epitaxial layer includes a first type semiconductor layer, an active layer and a second type semiconductor layer, which are formed on the pattern of the conductive layer successively; forming a first electrode on the second type semiconductor layer; dicing the substrate into a plurality of pieces or dies; performing an extending treatment to form a separating space between the pieces; dropping a conductive resin in the separating space to form the conductive structure on a lateral side of the piece; and forming a second electrode on the lateral side of each of the pieces. In some embodiment of the present disclosure, the separating space is about 500 μm.

In the following, an LED chip manufactured from the LED substrate as described herein will be described in detail with reference to FIG. 8.

Referring to FIG. 8, the LED chip comprises: an LED substrate 820 as described hereinabove and an epitaxial layer. The epitaxial layer may comprise: a first type semiconductor layer 840 formed on the first surface of the LED substrate 820, an active layer 850 formed on the first type semiconductor layer 840, and a second type semiconductor layer 860 formed on the active layer 850; a first electrode 810 formed on the second surface (bottom surface) of the base; and a second electrode 870 formed on the second type semiconductor layer 860. In some embodiment, the first type semiconductor layer 840 is an N type semiconductor layer and the second semiconductor layer 860 is a P type semiconductor. In other embodiments, the first type semiconductor layer 840 is a P type semiconductor layer and the second semiconductor layer 860 is an N type semiconductor. The first type semiconductor layer 840 or the second type semiconductor layer 860 is formed from the III-V group nitride material such as GaN, InGaN, AlGaN and AlGaInN. The active layer 850 is a multi-quantum well light emitting layer. The first electrode 810 or the second electrode 870 is formed from gold or aluminum.

In some embodiment, the LED chip may be a vertical structure LED chip. The LED chip is connected to a power supply (not shown) through the first electrode 810 and the second electrode 870, and the active layer 850 generates light when current passes through the active layer 850. Because the transverse current liquidity of the first type semiconductor layer or the second type semiconductor layer formed from the III-V group nitride material is poor, the light emitting efficiency of the conventional LED chip is low. In the present disclosure, the substrate of the LED chip comprises the conductive structure comprising the patterned conductive portion, the current may be distributed accordingly, thus improving the uniformity of the current and consequently improving the light emitting efficiency of the LED chip. Further, the base of the substrate is partly covered by the conductive structure, so the first electrode may be formed on the substrate easily, which may decrease the manufacturing complexities. To improve the conductivity of the LED chip, in some embodiment of the present disclosure, the LED chip further comprises a heavily-doped N type GaN layer 830 formed on the substrate 820. The heavily-doped N type GaN layer 830 may improve the lattice quality of the epitaxial layer.

In the present disclosure, the process of manufacturing the LED chip as described will be described briefly. The process for manufacturing the LED chip comprises steps of: providing an LED substrate 820 as mentioned above; forming an epitaxial layer on the first surface of the LED substrate 820, in which the epitaxial layer includes a first type semiconductor layer 840, an active layer 850 and a second type semiconductor layer 860, which are formed on the first surface of the LED substrate 820 successively; forming a first electrode 810 on the third surface of the base; and forming a second electrode 870 on the second type semiconductor layer 860. In some embodiments of the present disclosure, the epitaxial layer is formed through metal-organic chemical vapor deposition process. In some embodiment, the first type semiconductor layer 840 is an N type semiconductor layer and the second type semiconductor layer 860 is a P type semiconductor. In other embodiments, the first type semiconductor layer 840 is a P type semiconductor layer and the second type semiconductor layer is an N type semiconductor. The first type semiconductor layer 840 or the second type semiconductor layer 860 is formed from the III-V group nitride material such as GaN, InGaN, AlGaN and AlGaInN. The first electrode 810 or the second electrode 870 is formed from gold or aluminum. To improve the conductivity of the LED chip, in some embodiments of the present disclosure, the method may further comprise a step of forming a heavily-doped N type GaN layer 830 on the LED substrate 820. The heavily-doped N type GaN layer 830 may improve the lattice quality of the epitaxial layer.

In some embodiment of the present disclosure, an LED chip comprises: an LED substrate as described hereinabove and an epitaxial layer. The epitaxial layer may comprise: a first type semiconductor layer formed on the first surface of the LED substrate, an active layer formed on the first type semiconductor layer, and a second type semiconductor layer formed on the active layer; a first electrode formed on the second surface (lateral surface) of the base; and a second electrode formed on the second type semiconductor layer.

It will be appreciated by those skilled in the art that changes could be made to the examples described above without departing from the broad inventive concept. It is understood, therefore, that this disclosure is not limited to the particular examples disclosed, but it is intended to cover modifications within the scope of the present disclosure as defined by the appended claims.

1. An LED substrate, comprising:
a base including a first surface and a second surface; and
a conductive structure formed on at least a part of the first surface and at least a part of the second surface, the part of the conductive structure formed on the first surface electrically connected to the part of the conductive structure formed on the second surface.

2. The LED substrate of claim 1, wherein the part of the conductive structure formed on the first surface comprises a pattern exposing a part of the first surface.

3. The LED substrate of claim 2, wherein the pattern is a plurality of non-intersecting lines or a grid-like pattern.

4. The LED substrate of claim 1, wherein the base further comprises a third surface, and the conductive structure is further formed on the third surface.

5. A method for forming an LED substrate, comprising:
A) providing a base including a first surface and a second surface;
B) coating a photoresist on the first surface of the base to form a photoresist layer, and a part of the photoresist layer coated on the first surface comprising a photoresist pattern;
C) forming an intermediate layer including a conductive material on the surfaces of the base uncovered by the photoresist layer;
D) removing the photoresist layer; and
E) performing a heat treatment to convert the intermediate layer into a conductive structure.

6. The method of claim 5, wherein the pattern formed on the photoresist layer is a plurality of non-intersecting lines or a plurality of projections.

7. The method of claim 6, wherein each of the non-intersecting lines or the projections comprises a plurality of peripheral sides thereof being slanted toward each other by acute angles respectively with respect to the first surface of the base.

8. The method of claim 7, wherein the acute angles range from 20° to 70° respectively.

9. The method of claim 5, wherein the photoresist layer has a thickness of about 1.8-3 μm.

10. The method of claim 5, wherein the photoresist is a negative photoresist.

11. The method of claim 5, wherein the step B) comprises:
B1) coating a negative photoresist on the first surface of the base by a coating machine at a rotation speed of about 30 rps-45 rps for about 35 seconds or at a rotation speed of about 8 rps-11 rps for about 10 seconds;
B2) baking the base with the first surface being coated with the photoresist for about 12-16 minutes at a temperature of about 85-95° C.;
B3) exposing the base by a light source with an energy of 20 J for about 6-12 seconds by a distance of about 60-250 μm;
B4) developing the base for about 50-70 seconds and washing the base with water to form the photoresist layer with a photoresist pattern; and
B5) baking the base for about 20-30 minutes at a temperature of about 118-122° C.

12. The method of claim 5, wherein the step B) further comprises:
coating the negative photoresist on another one or more surfaces of the base.

13. The method of claim 5, wherein the intermediate layer is formed from a gelatinous precursor formed by a sol-gel method comprising the steps of dissolving a metal alkoxide and a polymer in an organic solvent and stirring the organic solvent at a temperature of about 40-90° C. to form the gelatinous precursor.

14. The method of claim 13, wherein the organic solvent is at least one solvent selected from ethanol, ethylene glycol, isopropanol and acetonitrile, and the polymer is polyvinyl alcohol, polyaniline or polypyrrole.

15. The method of claim 14, wherein the metal alkoxide is aluminum isopropoxide or silver isopropoxide, and the polymer is polyvinyl alcohol.

16. The method of claim 15, wherein the molar ratio of alcohol to metal is about 5:1 and the concentration of aluminum isopropoxide or silver isopropoxide is about 0.5-1.4 mol/L.

17. The method of claim 5, wherein the step E) further comprises:
putting the substrate in an annealing furnace filled with protection gas;
maintaining the temperature of the annealing furnace in a range of about 200-400° C. for about 1-2 hours; and
cooling the substrate in the furnace to room temperature.

18. A method for forming an LED chip, comprising:
providing an LED substrate comprising a base including a first surface and a second surface, and a conductive structure formed on at least a part of the first surface and at least a part of the second surface, wherein the part of the conductive structure formed on the first surface electrically connected to the part of the conductive structure formed on the second surface and the part of the conductive structure formed on the first surface comprises a pattern exposing a part of the first surface;
forming an epitaxial layer on the conductive structure formed on the first surface, wherein the epitaxial layer includes a first type semiconductor layer, an active layer and a second type semiconductor layer, which are formed on the pattern of the conductive structure successively;
forming a first electrode on a part of the conductive structure disposed on the second surface or of the base; and
forming a second electrode on the second type semiconductor layer.

19. The method of claim 18, further comprising the steps of:
dicing the substrate into a plurality of pieces;
performing an extending treatment to form a separating space between the pieces;
dropping a conductive resin in the separating space to form the conductive structure on at least one lateral side of the piece to electrically connect the part of the conductive structure formed on the first surface of the base with the part of the conductive structure formed on the second surface.

20. The method of claim 19, wherein the separating space is about 500 μm.

21-24. (canceled)
